(19) United States
(12) Patent Application Publication
(10) Pub. No.: US 2026/0068372 A1
(43) Pub. Date: Mar. 5, 2026

(54) SEMICONDUCTOR DEVICE

(71) Applicant: EPISTAR CORPORATION, Hsinchu (TW)

(72) Inventors: Jih-Kang Chen, Hsinchu (TW); Wei-Chun Liao, Hsinchu (TW); Chia-Chieh Wei, Hsinchu (TW)

(21) Appl. No.: 18/821,691

(22) Filed: Aug. 30, 2024

(51) Int. Cl. H01L 33/62; H01L 33/38

(52) U.S. Cl. CPC H10H 20/857; H10H 20/8312

(57) ABSTRACT

The present disclosure provides a semiconductor device. The semiconductor device includes a semiconductor stack, a first conductive structure electrically connecting to the semiconductor stack, a first insulative structure covering the first conductive structure, and a first electrode structure electrically connecting to the first conductive structure. The semiconductor stack includes a first portion having a first upper surface, and a second portion connecting to the first portion and having a second upper surface and a first side surface connecting the first upper surface and the second upper surface. The first conductive structure covers the first upper surface, the second upper surface and the first side surface. The first electrode structure locates on the first portion.

### BACKGROUND

### Technical Field

The present disclosure relates to semiconductor device, and in particular it relates to a semiconductor device including a conductive structure.

### Description of the Related Art

Semiconductor elements are widely used, and the research and development of related materials are also continuously being carried out. For example, III-V semiconductor materials containing group III and group V elements may be applied to various optoelectronic semiconductor elements, such as light-emitting chips (light-emitting diodes or laser diodes), light-absorbing chips (photodetectors or solar cells) or non-luminous chips (power components of switches or rectifiers), which can be used in lighting, medical treatment, display, communication, sensing, power supply systems and other applications.

With the development of science and technology, there are still many technical research and development needs for semiconductor components. Although existing semiconductor devices have generally met various needs, they are not satisfactory in all aspects and further improvements are still needed.

### BRIEF SUMMARY

The present disclosure provides a semiconductor device. The semiconductor device includes a semiconductor stack, a first conductive structure electrically connecting to the semiconductor stack, a first insulative structure covering the first conductive structure, and a first electrode structure electrically connecting to the first conductive structure. The semiconductor stack includes a first portion having a first upper surface, and a second portion connecting to the first portion and having a second upper surface and a first side surface connecting the first upper surface and the second upper surface. The first conductive structure covers the first upper surface, the second upper surface and the first side surface. The first electrode structure locates on the first portion.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion FIG. 1A illustrates a cross-sectional view of the semiconductor device, in accordance with some embodiments of the present disclosure.

FIG. 1B illustrates a cross-sectional view of an enlarged part circled by dash line of the semiconductor device shown in FIG. 1A.

FIG. 1C illustrates a part of a cross-sectional view of the semiconductor device, in accordance with some embodiments of the present disclosure.

FIG. 1D illustrates a part of a cross-sectional view of the semiconductor device, in accordance with some embodiments of the present disclosure.

FIG. 2 illustrates a top-view of a semiconductor device, in accordance with some embodiments of the present disclosure.

FIG. 3A illustrates a part of a top-view of the semiconductor device, in accordance with some embodiments of the present disclosure.

FIG. 3B illustrates a part of a top-view of the semiconductor device, in accordance with some embodiments of the present disclosure.

FIG. 4 illustrates a cross-sectional view of a semiconductor device, in accordance with some embodiments of the present disclosure.

FIG. 5A illustrates a part of a top-view of the semiconductor device, in accordance with some embodiments of the present disclosure.

FIG. 5B illustrates a part of a top-view of the semiconductor device, in accordance with some embodiments of the present disclosure.

FIG. 6A illustrates a cross-sectional view of a semiconductor apparatus, in accordance with some embodiments of the present disclosure.

FIG. 6B illustrates a top-view of a semiconductor apparatus, in accordance with some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

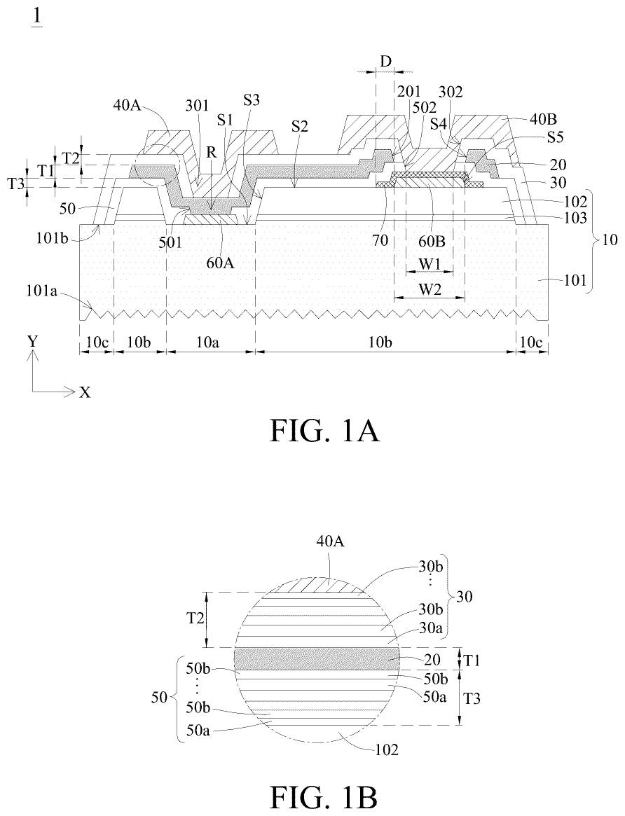

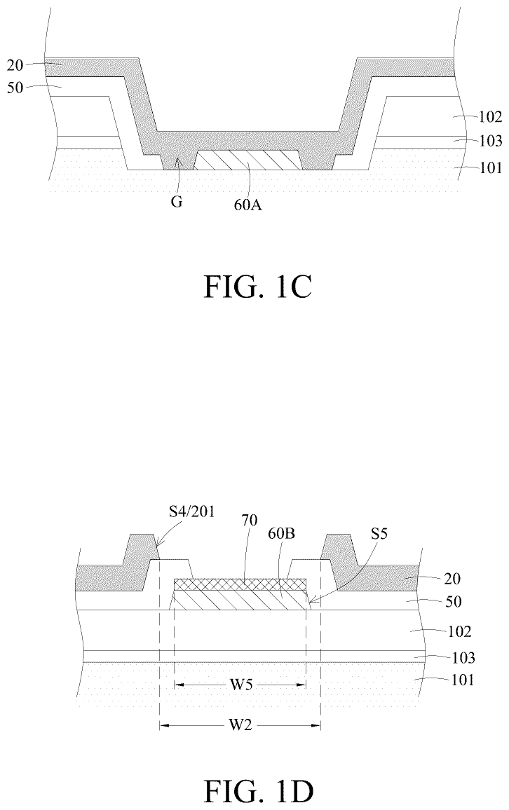

FIG. 1A shows a cross-sectional view of a semiconductor device 1, in accordance with some embodiments of the present disclosure. FIG. 2 shows a top-view of the semiconductor device 1. FIG. 1A shows a cross-sectional view along A-A line in FIG. 2. The semiconductor device 1 includes a semiconductor stack 10, a first conductive structure 20, a first insulative structure 30, a first electrode structure 40A and a second electrode structure 40B. The semiconductor stack 10 includes a first portion 10a and a second portion 10b connecting to the first portion 10a. In some embodiments, the semiconductor stack 10 includes a first semiconductor structure 101, a second semiconductor structure 102 and an active structure 103 between the first semiconductor structure 101 and the second semiconductor structure 102. The first portion 10a includes a part of the first semiconductor structure 101 and is devoid of the second semiconductor structure 102 and the active structure 103. The second portion 10b includes a part of the first semiconductor structure 101, the active structure 103 and the second semiconductor structure 102 sequentially located on the first semiconductor structure 101 in a stacking direction. In the embodiment, the semiconductor stack 10 further optionally includes a third portion 10c. The third portion 10c includes a part of the first semiconductor structure 101 and is devoid of the second semiconductor structure 102 and the active structure 103. The second portion 10b is between the first portion 10a and the third portion 10c. In the embodiment, the semiconductor stack 10 further includes a recess R corresponding to the first portion 10a. More specifically, the recess R is surrounded by the second portion 10b from a top view of the semiconductor device 1 as shown in FIG. 2.

In the embodiment, the first semiconductor structure 101 includes a first surface 101a and a second surface 101b opposite to the first surface 101a. The active structure 103 and the second semiconductor structure 102 sequentially locate on the second surface 101b. In the embodiment, the light emitted from the active structure 103 goes outside from the first surface 101a. In some embodiments, the first surface 101a can be a rough surface for increasing the light extraction efficiency of the semiconductor device 1.

The first portion 10a includes a first upper surface S1. The second portion 10b includes a second upper surface S2 and a first side surface S3 connecting to the second upper surface S2 and the first upper surface S1. The first conductive structure 20 covers the first upper surface S1, the second upper surface S2 and the first side surface S3. The first conductive structure 20 electrically connects to the semiconductor stack 10 via the first portion 10a.

The semiconductor device 1 further includes a second insulative structure 50 between the semiconductor stack 10 and the first conductive structure 20. In the embodiment as shown in FIGS. 1A and 2, the semiconductor device 1 can optionally include a first contact layer 60A on the first portion 10a and/or a second contact layer 60B on the second portion 10b. More specifically, the first contact layer 60A locates between the first upper surface S1 of the first portion 10a and the first conductive structure 20. The second contact layer 60B locates between the second upper surface S2 of the second portion 10b and the first conductive structure 20. The second insulative structure 50 covers the first portion 10a and the second portion 10b and includes a first via 501 on the first upper surface S1 and the second via 502 on the second upper surface S2. In this embodiment, a part of the first contact layer 60A is covered by the second insulative structure 50 and other part of the first contact layer 60A is devoid of being covered by the second insulative structure 50. The first via 501 locates corresponding to the other part of the first contact layer 60A. The first conductive structure 20 electrically connects to the first contact layer 60A through the first via 501. Similarly, a part of the second contact layer 60B is covered by the second insulative structure 50. Other part of the second contact layer 60B is devoid of being covered by the second insulative structure 50. The second via 502 locates corresponding to the other part of the second contact layer 60B. In some embodiments, as shown in FIG. 1C, the first contact layer 60A is not covered by the second insulative structure 50 and separated from the second insulative structure 50 by a gap G or a distance. The first conductive structure 20 fills into the gap G and covers a sidewall of the first contact layer 60A.

The first conductive structure 20 covers the second insulative structure 50 and the first contact layer 60A. The first conductive structure 20 includes a second side surface S4 and a first hole 201 corresponding to the position of the second upper surface S2 of the second semiconductor structure 102. The first hole 201 is defined by the second side surface S4. More specifically, the first hole 201 locates corresponding to the second via 502 and the second contact layer 60B, and the second side surface S4 connects to the second insulative structure 50. The second via 502 includes a first width W1 and the first hole 201 includes a second width W2 larger than the first width W1, from a cross-sectional view of the semiconductor device 1 as shown in FIG. 1A. The first conductive structure 20 can be a single layer or multiple layers. In the embodiment, the first conductive structure 20 has a first reflectivity to a light emitted by the active structure 103. The first reflectivity is 80%˜99%. The first conductive structure 20 includes a first thickness T1 along the stacking direction of the semiconductor stack 10, such as Y-axis as shown in FIG. 1A. The first thickness T1 is 0.05 μm˜0.5 μm.

The first insulative structure 30 covers the first conductive structure 20, the second insulative structure 50 and a part of the third portion 10c of the semiconductor stack 10. The first insulative structure 30 further includes a first opening 301 corresponding to the first upper surface S1 of the first portion 10a, and a second opening 302 corresponding to the second upper surface S2 of the second portion 10b. A part of the first conductive structure 20 is devoid of being covered by the first insulative structure 30. In the embodiment, the first insulative structure 30 directly contacts and covers the second side surface S4 of the first conductive structure 20.

In FIG. 2, the second opening 302 includes a third width W3 larger than the first width W1 of the second via 502 and smaller than the second width W2 of the first hole 201. The first insulative structure 30 can be a single layer or multiple layers. In the embodiment, the first insulative structure 30 has a second reflectivity to a light emitted by the active structure 103. For example, the second reflectivity is 80%˜99%. The first insulative structure 30 includes an electrically insulative material, such as silicon oxide, aluminum oxide, titanium oxide, tantalum oxide, gallium oxide, silicon nitride, titanium nitride or organic polymer. The first insulative structure 30 includes a second thickness T2 along the stacking direction of the semiconductor stack 10, such as Y-axis as shown in FIG. 1A. The second thickness T2 is 0.1 μm˜3 μm. In the embodiment as shown in FIG. 1B, the first insulative structure 30 includes a first layer 30a and a second layer 30b alternatively stacking to form a distributed Bragg reflector (DBR) structure.

Similarly, the second insulative structure 50 can be a single layer or multiple layers. In the embodiment, the second insulative structure 50 has a third reflectivity to a light emitted by the active structure 103. For example, the third reflectivity is 80%˜99%. The second insulative structure 50 includes an electrically insulative material, such as silicon oxide, tantalum oxide, gallium oxide, aluminum oxide, titanium oxide, silicon nitride, titanium nitride or organic polymer. The second insulative structure 50 includes a third thickness T3 along the stacking direction of the semiconductor stack 10, such as Y-axis as shown in FIG. 1B. The third thickness T3 is 0.1 μm˜3 μm.

In the embodiment as shown in FIG. 1B, the second insulative structure 50 includes a third layer 50a and a fourth layer 50b alternatively stacking to form a distributed Bragg reflector (DBR) structure. In some embodiments, the first insulative structure 30 includes DBR, and the second insulative structure 50 is devoid of DBR structure. In some embodiments, there is no DBR structure between the semiconductor stack 10 and the first conductive structure 20. In some embodiments, the second insulative structure 50 can be single layer or double layer with different insulating materials. The second thickness T2 of the first insulative structure 30 is greater than the third thickness T3 of the second insulative structure 50. The second reflectivity of the first insulative structure 30 is larger than the third reflectivity of the second insulative structure 50. In other embodiments, the first insulative structure 30 is devoid of DBR structure and the second insulative structure 50 includes DBR. The first insulative structure 30 can be single layer or double layer with different insulating materials. The second thickness T2 of the first insulative structure 30 is smaller than the third thickness T3 of the second insulative structure 50. In some embodiments, each of the first insulative structure 30 and the second insulative structure 50 are respectively devoid of DBR structure.

The first electrode structure 40A locates on the first insulative structure 30 and electrically connects to the first conductive structure 20 through the first opening 301 of the first insulative structure 30. The first electrode structure 40A and the second electrode structure 40B locate on the same side of the first semiconductor structure 101. Therefore, the semiconductor device 1 is a horizontal type structure. The second electrode structure 40B locates on the first insulative structure 30 and electrically connects to the second contact layer 60B through the second via 502 and the second opening 302. In the embodiment shown in FIG. 1, the second electrode structure 40B separates from the first conductive structure 20 by the first insulative structure 30. In the embodiment, the first conductive structure 20 and the first electrode structure 40A fill in the recess R of the semiconductor stack 10.

In the embodiment, the semiconductor device 1 further optionally includes a second conductive structure 70 covering the second contact layer 60B and directly contacting a part of the second upper surface S2 for reflecting the light emitted from the active structure 103 toward the first semiconductor structure 101. The second conductive structure 70 electrically connects to the second contact layer 60B and the second semiconductor structure 102. Besides, the first conductive structure 20 separates from the second conductive structure 70 by the second insulative structure 50.

The second contact layer 60B includes a fourth width W4 and the second conductive structure 70 includes a fifth width W5 larger than the fourth width W4, as shown in FIG. 2. The second contact layer 60B further includes a fifth side surface S5 connecting to the second upper surface S2, and the second conductive structure 70 covers the second upper surface S2 and the fifth side surface S5. The second conductive structure 70 overlaps with the first conductive structure 20 in the stacking direction of the semiconductor stack 10, such as Y-axis as shown in FIG. 1A. From the cross-sectional view of the semiconductor device 1 as shown in FIG. 1A, there is an overlapping width between the second conductive structure 70 and the first conductive structure 20, and the overlapping width includes a distance between 0.5 μm˜3 μm.

In other embodiments, the second conductive structure 70 only covers an upper surface of the second contact layer 60B and is devoid of covering the fifth side surface S5 of the second contact layer 60B. More specifically, in the embodiment as shown in FIG. 1D, since the fifth width W5 of the second conductive structure 70 is smaller than the second width W2 of the first hole 201 of the first conductive structure 20, the second conductive structure 70 is devoid of overlapping with the first conductive structure 20 in the stacking direction of the semiconductor stack 10.

The second conductive structure 70 can be a single layer or multiple layers. In the embodiment, the second conductive structure 70 has a fourth reflectivity to a light emitted by the active structure 103. The fourth reflectivity is 80%˜99%.

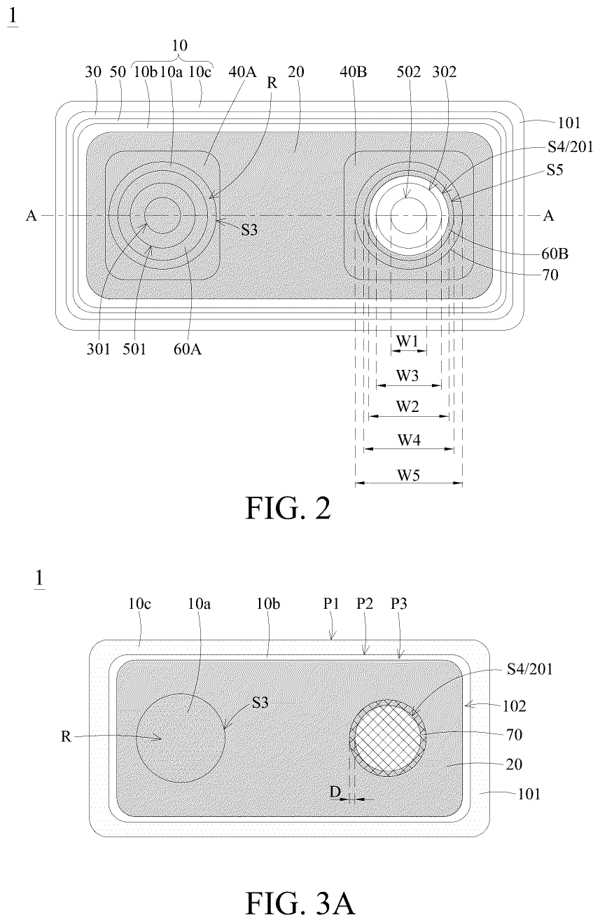

FIG. 3A shows a top-view of a semiconductor device 1, in accordance with some embodiments of the present disclosure. For the sake of clarity, FIG. 3A omits some structures in the semiconductor device 1, and only shows the distributions of the first portion 10a, the second portion 10b and the third portion 10c of the semiconductor stack 10, the first conductive structure 20, and the second conductive structure 70. More specifically, the distribution of the first semiconductor structure 101 is shown by dot background, the distribution of the first conductive structure 20 is shown by gray background, and the distribution of the second conductive structure 70 is shown by checked background in FIG. 3A. As shown in FIG. 3A, the second portion 10b surrounds the first portion 10a, and the third portion 10c surrounds the second portion 10b. From top view of the semiconductor device 1, the first semiconductor structure 101 includes a first outer periphery P1, the second semiconductor structure 102 includes a second outer periphery P2 and the first conductive structure 20 includes a third outer periphery P3, and the second outer periphery P2 is between the first outer periphery P1 and the third outer periphery P3. A part of the second semiconductor structure 102 is devoid of being covered by the first conductive structure 20. From a top view of the semiconductor device 1, the first outer periphery P1 indicates the outermost line of the first semiconductor structure 101, the second outer periphery P2 indicates the outermost line of the second semiconductor structure 102, and the third outer periphery P3 indicates the outermost line of first conductive structure 20.

From a top view of the semiconductor device 1 as shown in FIG. 3A, the first conductive structure 20 includes a first area and the second semiconductor structure 102 includes a second area smaller than or equal to the first area. In some embodiments, a ratio of the first area to the second area is 0.6˜1. Since the first conductive structure 20 covers the second upper surface S2 of the second portion 10b and the first side surface S3 of the semiconductor stack 10, the light emitted from the active structure 103 can be reflected toward the first semiconductor structure 101. Therefore, the light extraction efficiency and the brightness of the semiconductor device 1 can be enhanced by the first conductive structure 20. More specifically, in the embodiment, the first conductive structure 20 covers the second upper surface S2 except the area corresponding to the second contact layer 60B, and further extends to the recess R of the semiconductor stack 10 and covers the first upper surface S1 of the first portion 10a. Thus, the first area of the first conductive structure 20 can be enlarged as much as possible, and the light emitted from the active structure 103 can be reflected and the brightness of the semiconductor device can be further enhanced.

In the embodiment, the second conductive structure 70 includes a third area smaller than the first area of the first conductive structure 20 and the second area of the second semiconductor structure 102. A ratio of the third area to the second area is 0.05˜0.5. Since the second conductive structure 70 covers the part of the second upper surface S2 where is devoid of covered by the first conductive structure 20, the light emitted from the active structure 103 can be further reflected toward the first semiconductor structure 101. Therefore, the light extraction efficiency and the brightness of the semiconductor device 1 can be further enhanced by the second conductive structure 70. In the embodiment, the first insulative structure 30 includes a fourth area larger than the first area of the first conductive structure 20, the second area of the second semiconductor structure 102 and the third area of the second conductive structure 70.

FIG. 3B shows a top-view of a semiconductor device 2, in accordance with some embodiments of the present disclosure. In the embodiment, the third outer periphery P3 of the first conductive structure 20 is between the first outer periphery P1 of the first semiconductor structure 101 and the second outer periphery P2 of the second semiconductor structure 102. The second semiconductor structure 102 is covered by the first conductive structure 20 except the area corresponding to the second contact layer 60B, and the first conductive structure 20 further extends to cover the third portion 10c of the first semiconductor structure 101. In the embodiment, the first conductive structure 20 includes a first area and the second semiconductor structure 102 includes a second area smaller than the first area, and a ratio of the first area to the second area is 1.1˜1.6.

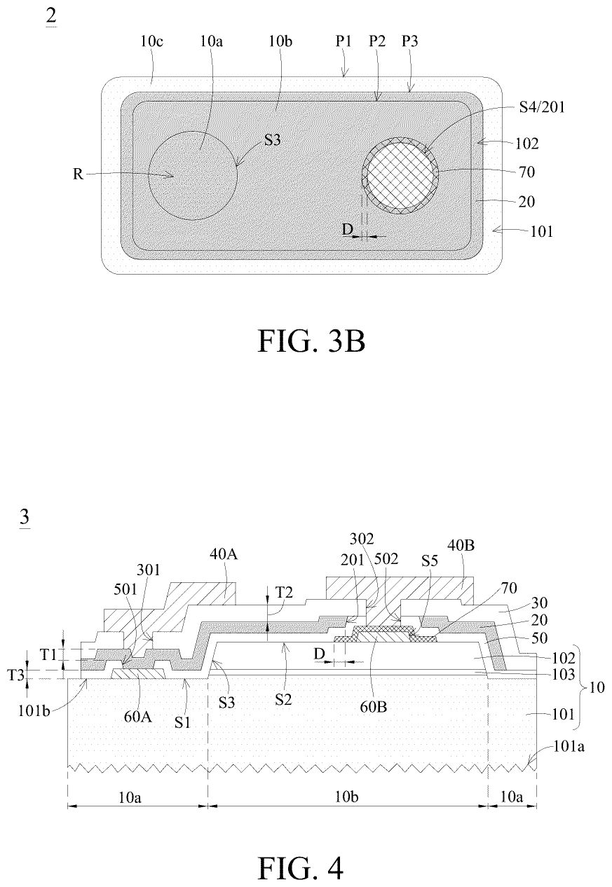

FIG. 4 shows a cross-sectional view of a semiconductor device 3, in accordance with some embodiments of the present disclosure. The structures and the connection between the structures of the semiconductor device 3 are similar to that of the semiconductor device 1 as shown in FIGS. 1A and 2. The semiconductor stack 10 of the semiconductor device 3 includes a first portion 10a and a second portion 10b surrounded by the first portion 10a. The semiconductor stack 10 of the semiconductor device 3 is devoid of the third portion, which is different from the semiconductor device 1.

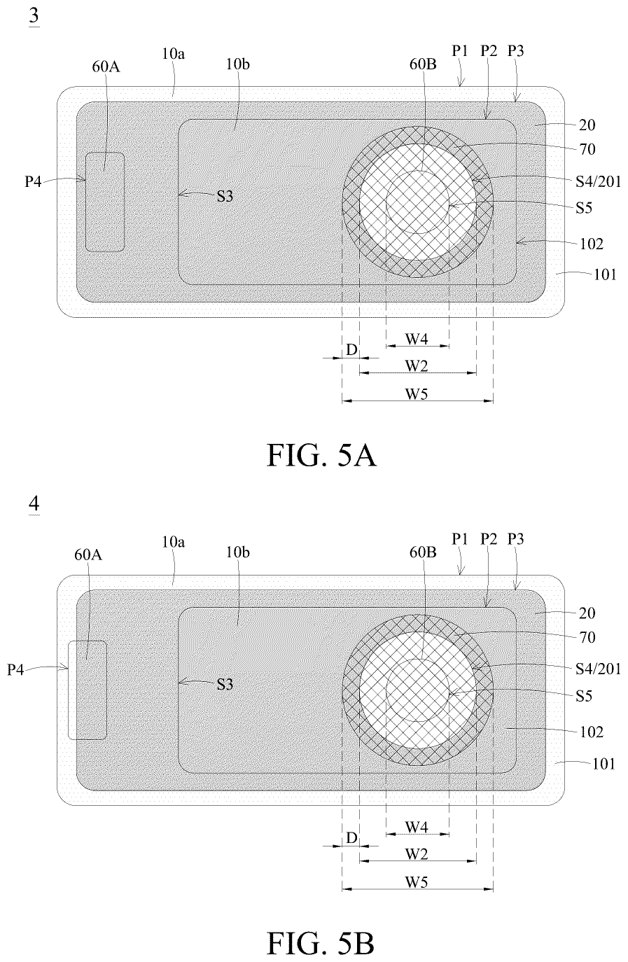

FIG. 5A shows a top view of the semiconductor device 3, in accordance with some embodiments of the present disclosure. The first conductive structure 20 includes a first area and the second semiconductor structure 102 includes a second area smaller than the first area. In the embodiment, a ratio of the first area to the second area is 1.2˜1.8. Besides, the first semiconductor structure 101 includes a fifth area larger than the first area. A ratio of the first area to the fifth area is 0.7˜0.95. From a top view of the semiconductor device 3, the first semiconductor structure 101 includes a first outer periphery P1, the second semiconductor structure 102 includes a second outer periphery P2 and the first conductive structure 20 includes a third outer periphery P3 between the first outer periphery P1 and the second outer periphery P2. The first contact layer 60A locates on the first upper surface S1 and includes a fourth outer periphery P4 surrounded by the third outer periphery P3. In the embodiments, the first conductive structure 20 fully covers the first contact layer 60A.

FIG. 5B shows a top-view of a semiconductor device 4, in accordance with some embodiments of the present disclosure. The structures and the connection between the structures of the semiconductor device 4 are similar to that of the semiconductor device 3 as shown in FIG. 5A. In the embodiments, a part of the first contact layer 60A is devoid of being covered by the first conductive structure 20, which is different from the relationship between the first contact layer 60A and the first conductive structure 20 of the semiconductor device 3.

The first semiconductor structure 101, the second semiconductor structure 102 and the active structure 103 can be obtained by epitaxial growth methods. Epitaxial growth methods include but are not limited to metal-organic chemical vapor deposition (MOCVD), hydride vapor phase epitaxy (HVPE), molecular beam epitaxy (MBE) or liquid-phase epitaxy (LPE). The first semiconductor structure 101 and the second semiconductor structure 102 may include a single layer or multiple layers, and each layer may include III-V semiconductor material. The above III-V semiconductor material may include aluminum (Al), gallium (Ga), arsenic (As), phosphorus (P), indium (In) or nitrogen (N). In some embodiments, each layer in the first semiconductor structure 101, the second semiconductor structure 102 and the active structure 103 includes indium or arsenic. In some embodiments, each layer in the first semiconductor structure 101, the second semiconductor structure 102 and the active structure 103 does not include nitrogen (N).

The first semiconductor structure 101 has a first conductivity type, and the second semiconductor structure 102 has a second conductivity type different from the first conductivity type. The first semiconductor structure 101 and the second semiconductor structure 102 can provide electrons and holes (or holes and electrons) respectively. For example, the first conductivity type is n-type and the second conductivity type is p-type, or the first conductivity type is p-type and the second conductivity type is n-type. The conductive types of the first semiconductor structure 101 and the second semiconductor structure 102 can be determined by adding different dopants. For example, the first semiconductor structure 101 includes a first dopant, and the second semiconductor structure 102 includes a second dopant that is different from the first dopant. The first dopant and the second dopant may be Group II, Group IV or Group VI elements in the periodic table of elements, such as magnesium (Mg), zinc (Zn), carbon (C), silicon (Si) or tellurium (Te). In some embodiments, the first dopant is silicon (Si) and the second dopant is magnesium (Mg). Alternatively, the first dopant is magnesium (Mg) and the second dopant is silicon (Si).

Electrons and holes can be combined in the active structure 103 to emit light with a peak wavelength. The light may be visible light or invisible light, and may be incoherent light or coherent light. Specifically, the above-mentioned peak wavelength may depend on the material of the active structure 103. For example, when the material of the active structure 103 includes AlGaN, it can emit ultraviolet light with a peak wavelength of 250 nm to 400 nm. When the material of the active structure 103 includes InGaN, it can emit deep blue light or blue light with a peak wavelength of 400 nm to 490 nm, or green light or yellow light with a peak wavelength of 490 nm to 550 nm, or red light with a peak wavelength of 560 nm to 650 nm. When the material of the active structure 103 includes InGaP or AlGaInP, it can emit yellow, orange or red light with a peak wavelength of 530 nm to 700 nm When the material of the active structure 103 includes InGaAs, InGaAsP, AlGaAs or AlGaInAs, it can emit infrared light with a peak wavelength of 700 nm to 1700 nm.

In some embodiments, the first contact layer 60A and the second contact layer 60B may include metal or alloy. For example, metal includes germanium (Ge), beryllium (Be), zinc (Zn), gold (Au), nickel (Ni) or copper (Cu). The alloy may include at least two above metals, such as germanium gold nickel (GeAuNi), beryllium gold (BeAu), germanium gold (GeAu) or zinc gold (ZnAu). The first insulative structure 30 and the second insulative structure 50 include a dielectric material, such as an oxide or a nitride. For example, the material of the first insulative structure 30 and the second insulative structure 50 can be tantalum oxide, aluminum oxide, silicon dioxide, titanium oxide, or silicon nitride. In some embodiments, the first insulative structure 30 and the second insulative structure 50 respectively include a reflective structure, such as a Distributed Bragg Reflector (DBR) structure. The first electrode structure 40A and the second electrode structure 40B may each include a single-layer or multi-layer structure. In some embodiments, the first electrode structure 40A and the second electrode structure 40B include nickel (Ni), titanium (Ti), platinum (Pt), palladium (Pd), silver (Ag), gold (Au), aluminum (Al), tin (Sn) and/or copper (Cu). In some embodiments, the first conductive structure 20 and the second conductive structure 70 may include an electrically conductive material, such as metal or metal alloy. For example, metal includes gold (Au), silver (Ag) or aluminum (Al). The alloy may include at least two above metals.

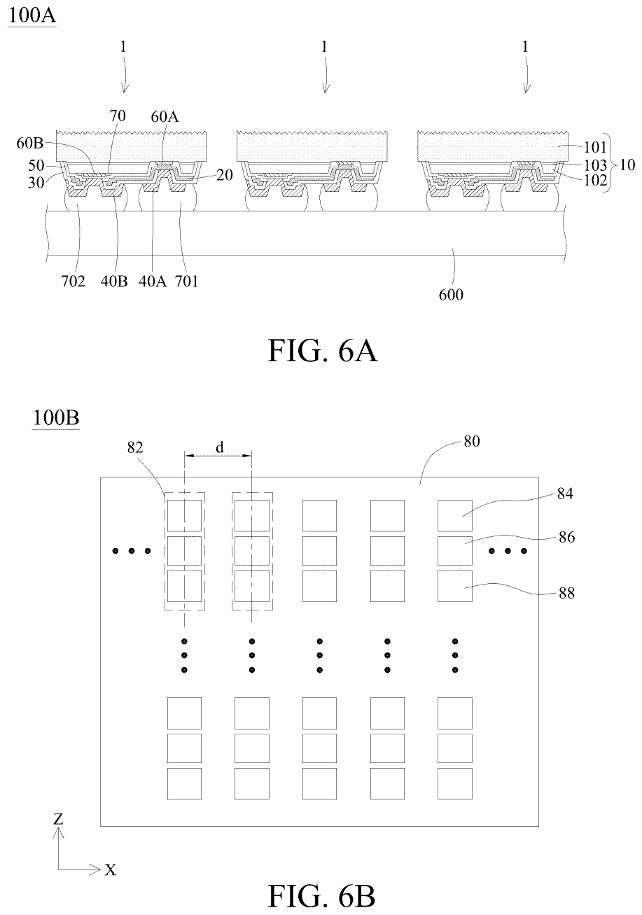

FIG. 6A is a cross-sectional view of a semiconductor apparatus, in accordance with some embodiments of the present disclosure. Specifically, FIG. 6A illustrates a semiconductor apparatus 100A formed by flip-chip bonding a plurality of semiconductor devices 1 to a carrier 600. The semiconductor apparatus 100A includes the carrier 600 and the plurality of semiconductor devices 1 located on the carrier 600. The carrier 600 includes a first conductive bump 701 and a second conductive bump 702 separated from the first conductive bump 701. The first conductive bump 701 connects the first electrode structure 40A, and the second conductive bump 702 connects the second electrode structure 40B. The carrier 600 is a package submount or a printed circuit board (PCB). The carrier 600 may include a single-layer or multi-layer structure. The material of the carrier 600 may include polyester (Polyester), polyimide (PI), BT resin (Bismaleimide Triazine), PTFE resin (Polytetrafluoroethylene), phenol resins (PF) or glass fiber epoxy resin. The material of the first conductive bump 701 and the second conductive bump 702 may include metal, such as tin (Sn). The positions, relative relationships, material compositions, and structural changes of other layers or structures in this embodiment have also been described in detail in previous embodiments and will not be described again here. The semiconductor device 1 here can be replaced by the semiconductor 2,3 or 4 in other embodiments. In some embodiments, the semiconductor apparatus 100A includes semiconductor device 1, 2, 3 and/or 4.

FIG. 6B is a top-view of a semiconductor apparatus, in accordance with some embodiments of the present disclosure. The semiconductor apparatus 100B of this embodiment is, for example, a display unit. As shown in FIG. 6B, the semiconductor apparatus 100B includes a carrier board 800 and a plurality of pixel units 82 located on the carrier board 800. The plurality of pixel units 82 is arranged in an array along the directions parallel to the X-axis and the Z-axis, and are arranged at an interval d in the direction parallel to the X-axis. The number of pixel units 82 can be adjusted according to needs. For example, in some embodiments, the plurality of pixel units 82 included in the semiconductor apparatus100B can provide a resolution of 1920×1080 pixels. In some embodiments, a distance d between the adjacent pixel units is less than 1.4 mm. For example, the distance d is between 0.2 mm and 1.3 mm, specifically such as 0.75 mm, 0.8 mm, 1 mm, and 1.25 mm. As shown in FIG. 6B, each pixel unit 82 includes a first semiconductor device 84, a second semiconductor device 86 and a third semiconductor device 88 arranged along a direction parallel to the Z-axis. One or more of the first semiconductor device 84, the second semiconductor device 86, and the third semiconductor device 88 may include semiconductor devices described in embodiments of the present disclosure (such as the aforementioned semiconductor device 1, 2, 3 and/or 4). In this embodiment, the first semiconductor 84, the second semiconductor element 86 and the third semiconductor element 88 are all light-emitting elements and can emit red light, green light and blue light respectively. In some embodiments, the arrangement order of these semiconductor devices 84, 86, 88 can also be adjusted according to needs. For example, the first semiconductor device 84, the second semiconductor device 86, and the third semiconductor device 88 emit red light, blue light, and green light respectively. Each pixel unit 82 can be electrically connected to a circuit (not shown) on the surface of the carrier board 800, so that the semiconductor device 84, 86, 88 therein can receive external signals and emit light according to the external signals. The structure and materials of the carrier board 800 can refer to the above description of the carrier 600. In some embodiments, the carrier board 800 is bendable and can withstand a curvature radius less than 50 mm, such as 25 mm or 32 mm.

According to embodiments of the present disclosure, the semiconductor device and semiconductor apparatus of the present disclosure can be applied to products in the fields of lighting, display, communication, power systems. For example, lamps, monitors, automotive instrument panels, televisions, computers, traffic signals, indoor displays and outdoor displays.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a semiconductor stack comprising:
a first portion comprising a first upper surface; and
a second portion connecting to the first portion and comprising a second upper surface and a first side surface connecting the first upper surface and the second upper surface;
a first conductive structure electrically connecting to the semiconductor stack, and covering the first upper surface, the second upper surface and the first side surface;
a first insulative structure covering the first conductive structure; and
a first electrode structure located on the first portion and electrically connecting to the first conductive structure.

2. The semiconductor device as claimed in claim 1, wherein the semiconductor stack comprises a first semiconductor structure, a second semiconductor structure and an active structure between the first semiconductor structure and the second semiconductor structure, and the first portion comprises the first semiconductor structure and is devoid of the second semiconductor structure and the active structure.

3. The semiconductor device as claimed in claim 1, further comprising a second electrode structure on the second portion, wherein the second electrode structure separates from the first conductive structure.

4. The semiconductor device as claimed in claim 1, wherein the first insulative structure comprises a first opening on the first conductive structure and the first electrode structure fills in the first opening.

5. The semiconductor device as claimed in claim 1, further comprising a second insulative structure between the semiconductor stack and the first conductive structure.

6. The semiconductor device as claimed in claim 1, wherein the first conductive structure comprises a first hole on the second portion.

7. The semiconductor device as claimed in claim 6, wherein the first insulative structure comprises a second opening corresponding to the first hole, and the first hole comprises a first width and the second opening comprises a second width smaller than the first width.

8. The semiconductor device as claimed in claim 1, wherein the semiconductor structure comprises a rough surface away from the first electrode structure.

9. The semiconductor device as claimed in claim 1, wherein in a top view of the semiconductor device, the semiconductor stack comprises a first side and a second side connecting to the first side, and the first side has a first length and the second side has a second length, and one of the first length and the second length is smaller than 100 μm.

10. The semiconductor device as claimed in claim 1, further comprising a first contact layer between the second upper surface and the first conductive structure.

11. The semiconductor device as claimed in claim 1, wherein the first conductive structure comprises a first area and the first insulative structure comprises a second area larger than the first area, from a top view of the semiconductor device.

12. The semiconductor device as claimed in claim 11, wherein the first conductive structure comprises a first area, the first insulative structure comprises a second area, and the first contact layer comprises a third area, and wherein the second area is larger than the first area, and the third area is smaller than the first area, from a top view of the semiconductor device.

13. The semiconductor device as claimed in claim 11, further comprising a second contact layer between the first upper surface and the first conductive structure.

14. The semiconductor device as claimed in claim 13, further comprising a second conductive structure covers the second contact layer and directly contacting a part of the second upper surface.

15. The semiconductor device as claimed in claim 15, wherein the first conductive structure separates from the second conductive structure.

16. The semiconductor device as claimed in claim 5, wherein the first insulative structure comprises a first thickness and the second insulative structure comprises a second thickness smaller than the first thickness.

17. The semiconductor device as claimed in claim 5, wherein the second insulative structure is devoid of distributed Bragg reflector.

18. The semiconductor device as claimed in claim 1, wherein the semiconductor stack further comprises a recess corresponding to the first portion, and the first conductive structure and the first electrode structure fill in the recess.

19. The semiconductor device as claimed in claim 5, wherein the first insulative structure comprises a reflectivity and the second insulative structure comprises a reflectivity smaller than the reflectivity of the first insulative structure.

20. The semiconductor device as claimed in claim 1, wherein the first conductive structure comprises a second side surface on the second portion, and the first insulative structure covers the second side surface.
